(19) United States
(12) Patent Application Publication
(10) Pub. No.: US 2011/0217846 A1
(43) Pub. Date: Sep. 8, 2011

(54) METHOD FOR MANUFACTURING SEMICONDUCTOR DEVICE

(75) Inventors: Katsuhiko ONISHI, Toyama (JP); Shin-ichi Imai, Osaka (JP)

(73) Assignee: Panasonic Corporation, Osaka (JP)

(21) Appl. No.: 13/107,500

(22) Filed: May 13, 2011

Related U.S. Application Data
(63) Continuation of application No. PCT/JP2009/005981, filed on Nov. 10, 2009.

(30) Foreign Application Priority Data
Jan. 27, 2009 (JP) 2009-015482

(51) Int. Cl. H01L 21/31

(52) U.S. Cl. 438/703; 257/E21.24

(57) ABSTRACT

To prevent the occurrence of short circuit or abnormality of wiring resistance values, a semiconductor wafer is subjected to nitrogen plasma treatment after one of the following steps is over; a step of providing a resist pattern on an inter-layer insulation film and then dry-etching the inter-layer insulation film, and a step of dry-etching a stressor SiN film after the resist pattern is removed.

### FIELD OF THE INVENTION

The present invention relates to a method for manufacturing a semiconductor device, more particularly to a method for manufacturing a semiconductor device provided with a stressor SiN film.

### BACKGROUND OF THE INVENTION

A flow of conventional manufacturing steps relating to a gate contact portion of a semiconductor device is described referring to FIGS. 1B and FIGS. 8A-8G. Gate electrodes 32 are formed on a semiconductor substrate (semiconductor wafer) 34. A gate electrode insulation film 31 is formed on each of the gate electrodes 32, and a side wall 33 is formed on side walls of the gate electrode 32 and the gate electrode insulation film 31 (see FIG. 8A). Next, an etching stop layer (nitride film) 36 is formed so as to cover the gate electrodes (see FIG. 8B). An inter-layer insulation film 37 is formed on the etching stop film 36 (see FIG. 8C), and an upper surface of the inter-layer insulation film 37 is flattened by, for example CMP. Then, a resist 38 is patterned by, for example, lithography (see FIG. 8D). Then, the resist pattern 38 is used as a mask to dry-etch the inter-layer insulation film 37 so that contact holes are formed (see FIG. 8E). The etching stop film 36 at bottoms of the contact holes is etched (see FIG. 8F), and the resist 38 is removed by ashing (see FIG. 8G).

A new material of semiconductor devices attracting attention in recent years is stressor SiN film as semiconductor integrated circuit devices are increasingly integrated, more highly-functional, and achieving a higher speed. When the mobility of carrier is improved by introducing distortion into a channel region, a highly-functional MOS transistor can be obtained, and it is necessary to use a semiconductor device material having a high stress to generate distortion for the purpose. The stressor SiN film has a high stress. When the stressor SiN film is deposited on a transistor formation region, distortion is introduced into the channel region, which improves the carrier mobility. This is the background of the popularity of stressor SiN film.

### PRIOR ART DOCUMENT

### Patent Document

### Patent Document 1: Unexamined Japanese Patent Applications Laid-Open No. 2002-164427

### Patent Document 2: Unexamined Japanese Patent Applications Laid-Open No. 2005-116801

### SUMMARY OF THE INVENTION

### Problem to Be Solved By the Invention

A technical disadvantage of the conventional technology is that the production yield of semiconductor devices is deteriorated by short circuit or abnormality of wiring resistance values in contact holes.

### Means For Solving the Problem

In the process of developing and accomplishing the present invention, the inventors of the present invention found out the following facts through various tests. A fluorocarbon-based gas used in dry etching turns into a polymer and adsorbs to a semiconductor wafer. When the semiconductor wafer is exposed to atmosphere, the gas adsorbed thereto may react with the moisture content of atmosphere, generating hydrofluoric acid.

In any conventional semiconductor integrated circuit devices in which the stressor SiN film is not yet used but a nitride film is provided, hydrofluoric acid may be similarly produced, but the nitride film is not thereby dissolved to such an extent that affects wiring resistances. Therefore, it is not necessary to remove the polymer. This is disclosed in the Patent Document 1.

The inventors of the present invention learnt how hydrofluoric acid was produced, and also learnt that the stressor SiN film was more easily dissolved by hydrofluoric acid. When the stressor SiN film is dissolved by hydrofluoric acid, contact between the stressor Sin film and the wiring materials W is lost, resulting in variability of wiring resistances around gates. Performing dry etching with Cu being exposed during the routing of Cu wiring, fluorocarbon-based gas used in the dry etching reacts with the wiring material Cu and causes corrosion of Cu, resulting in variability of wiring resistances.

A conventional means for solving the technical problem is to subject a semiconductor wafer, which is conventionally exposed to atmosphere after dry etching, to nitrogen plasma treatment as a preliminary treatment before being exposed to atmosphere to avoid the corrosion. This is disclosed in the Patent Document 2.

It was found out by the inventors of the present invention that this solving means is not so effective because the nitrogen plasma treatment after dry etching still fails to adequately prevent the polymer produced from the fluorocarbon-based gas from reacting with the stressor SiN film. The inventors also found out through various tests that the stressor SiN film can be dissolved by a trace level of hydrofluoric acid.

Based on the findings, the inventors of the present invention reached the conclusion that an overriding goal for successfully avoiding short circuit or abnormality of wiring resistance values in contact holes is to completely remove the fluorocarbon-based gas or prevent the gas from reacting with the moisture content of atmosphere.

A semiconductor device manufacturing method according to the present invention was accomplished based on the conclusion. The semiconductor device manufacturing method includes the following technical requirements: perform nitrogen plasma treatment in the case where the stressor SiN film is exposed after dry etching; increase a bias power to ensure the removal of a polymer produced from a fluorocarbon-based gas; shorten the stay of fluorine in a chamber to prevent re-adsorption of the fluorocarbon-based gas after the polymer produced from the fluorocarbon-based gas is removed; increase a nitrogen flow rate in the nitrogen plasma treatment to shorten the stay of fluorine, it is more effective to set a relatively high temperature because a time length for the gas adsorbed to a solid surface to stay thereon is temperature-dependent; transform the fluorine into a COF gas and evacuate the gas by introducing a carbon monoxide gas into the chamber after the nitrogen plasma treatment to completely remove the residual gas; and retain the post-treatment semiconductor wafer under a nitrogen atmosphere.

The semiconductor device manufacturing method according to the present invention can eliminate variability of wiring resistances conventionally caused by dissolution of the stressor SiN film.

### EFFECT OF THE INVENTION

The semiconductor device manufacturing method according to the present invention exerts the following effects:
in-plane variability of wiring resistances can be reduced; and
a semiconductor device with stable wiring resistances can be manufactured.

The semiconductor device manufacturing method according to the present invention thus technically advantageous can avoid short circuit or abnormality of wiring resistance values in contact holes, thereby preventing the production yield of a semiconductor device from deteriorating.

### BRIEF DESCRIPTION OF THE DRAWINGS

FIG. 1A is an illustration of a flow of steps in a semiconductor device manufacturing method according to an exemplary embodiment 1 of the present invention.

FIG. 1B is a conventional semiconductor device manufacturing method.

FIG. 2A is a schematic drawing of a first semiconductor device manufacturing step according to the present invention.

FIG. 2B is a schematic drawing of a second semiconductor device manufacturing step according to the present invention.

FIG. 2C is a schematic drawing of a third semiconductor device manufacturing step according to the present invention.

FIG. 2D is a schematic drawing of a fourth semiconductor device manufacturing step according to the present invention.

FIG. 2E is a schematic drawing of a fifth semiconductor device manufacturing step according to the present invention.

FIG. 2F is a schematic drawing of a sixth semiconductor device manufacturing step according to the present invention.

FIG. 2G is a schematic drawing of a seventh semiconductor device manufacturing step according to the present invention.

FIG. 3 is a schematic drawing of dissolution of a stressor SiN film which is a technical problem of a conventional semiconductor device manufacturing method.

FIG. 4 schematically illustrates a plasma treatment device according to the exemplary embodiment.

FIG. 5 is a sectional view schematically illustrating a structure of a chamber in the plasma treatment device according to the exemplary embodiment.

FIG. 6A is a schematic drawing of a first state illustrating a fluorine removal mechanism according to the present invention.

FIG. 6B is a schematic drawing of a second state illustrating the fluorine removal mechanism according to the present invention.

FIG. 6C is a schematic drawing of a third state illustrating the fluorine removal mechanism according to the present invention.

FIG. 6D is a schematic drawing of a fourth state illustrating the fluorine removal mechanism a according to the present invention.

FIG. 7 is an illustration of a flow of steps in a semiconductor device manufacturing method according to an exemplary embodiment 2 of the present invention.

FIG. 8A is a schematic drawing of a first semiconductor device manufacturing step according to prior art.

FIG. 8B is a schematic drawing of a second semiconductor device manufacturing step according to prior art.

FIG. 8C is a schematic drawing of a third semiconductor device manufacturing step according to prior art.

FIG. 8D is a schematic drawing of a fourth semiconductor device manufacturing step according to prior art.

FIG. 8E is a schematic drawing of a fifth semiconductor device manufacturing step according to prior art.

FIG. 8F is a schematic drawing of a sixth semiconductor device manufacturing step according to prior art.

FIG. 8G is a schematic drawing of a seventh semiconductor device manufacturing step according to prior art.

### EXEMPLARY EMBODIMENTS FOR CARRYING OUT THE INVENTION

### Exemplary Embodiment 1

As described earlier, wiring resistances around gates become variable because the stressor SiN film is dissolved by hydrofluoric acid produced by the reaction generated between the atmospheric moisture content and the polymer produced during dry etching when the stressor SiN film is exposed to atmosphere.

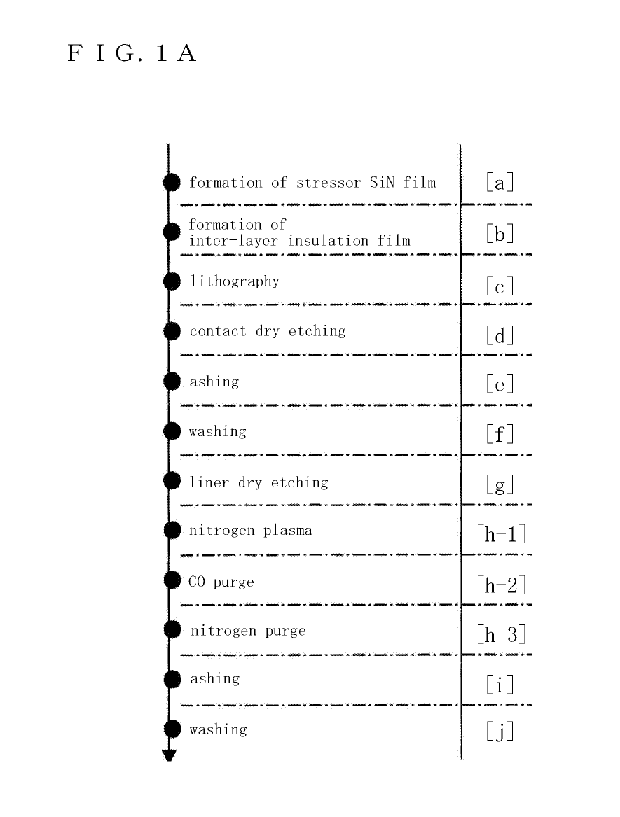

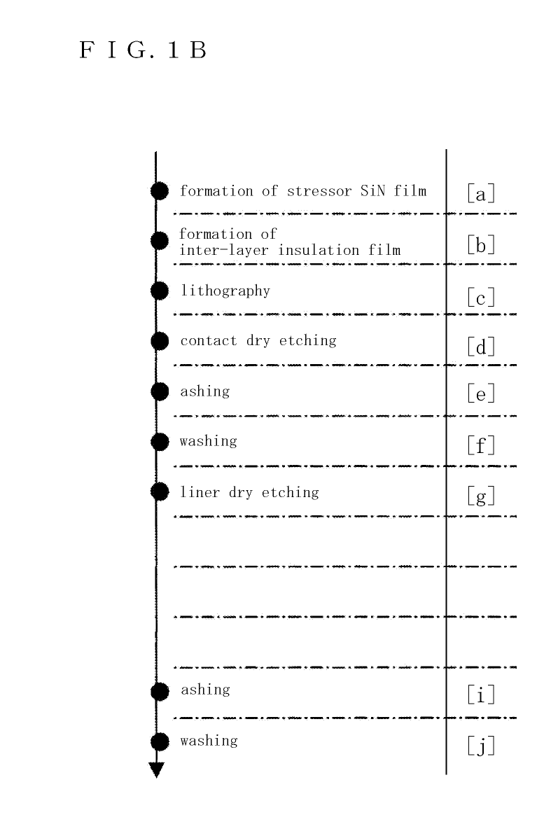

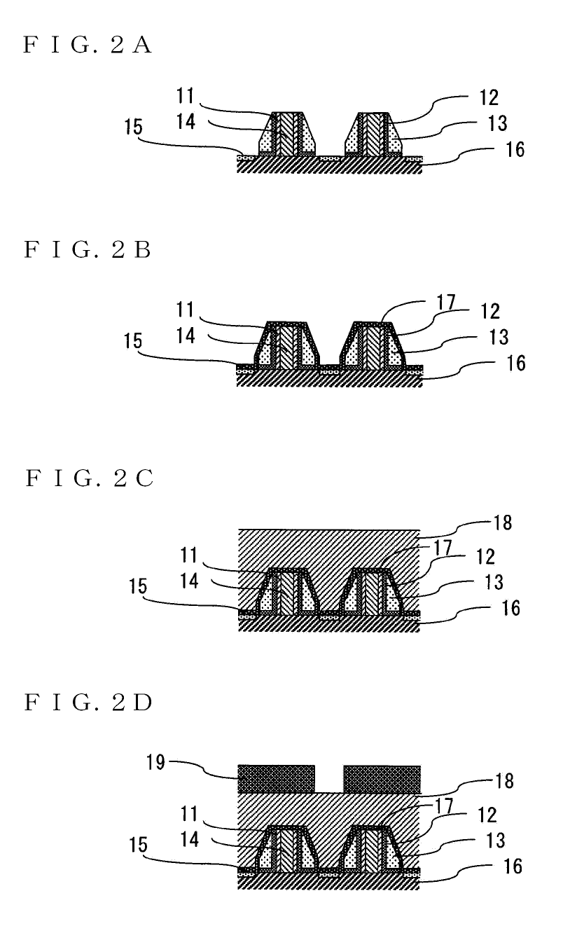

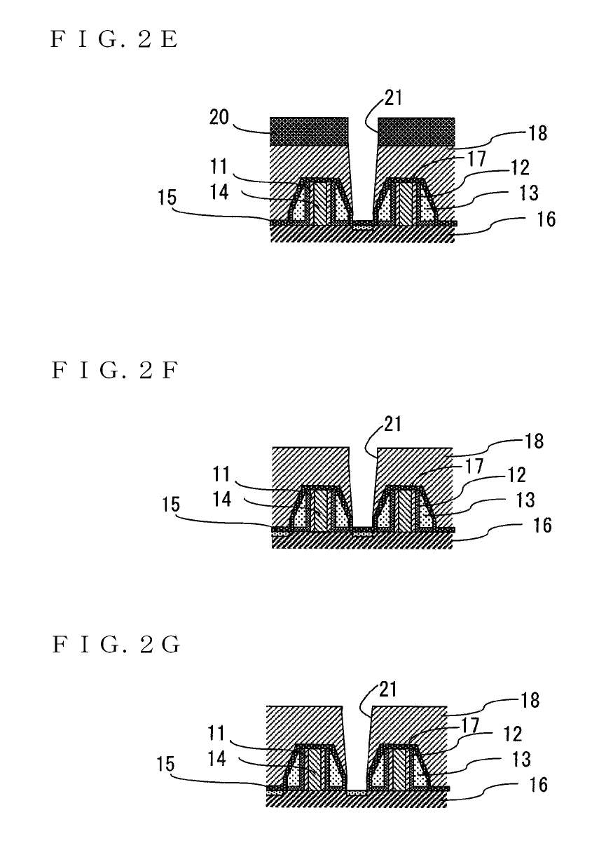

An exemplary embodiment 1 of the present invention solves the problem as described below. FIG. 1A illustrates a flow of main steps in a manufacturing method according to the present exemplary embodiment, and FIGS. 2 illustrate the respective steps in cross section. FIG. 1B illustrates a conventional flow of manufacturing steps as a comparative example to the present exemplary embodiment.

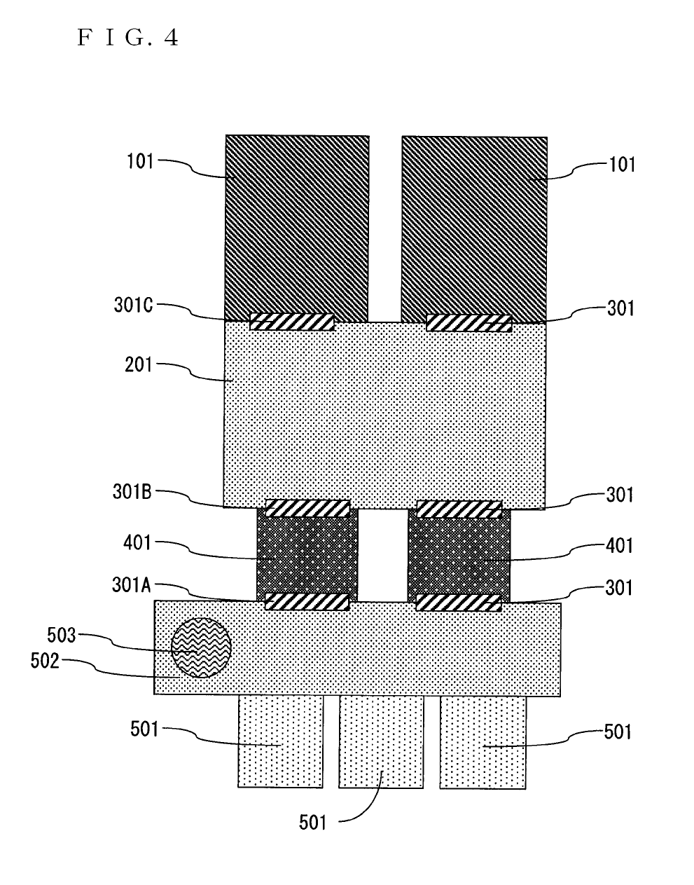

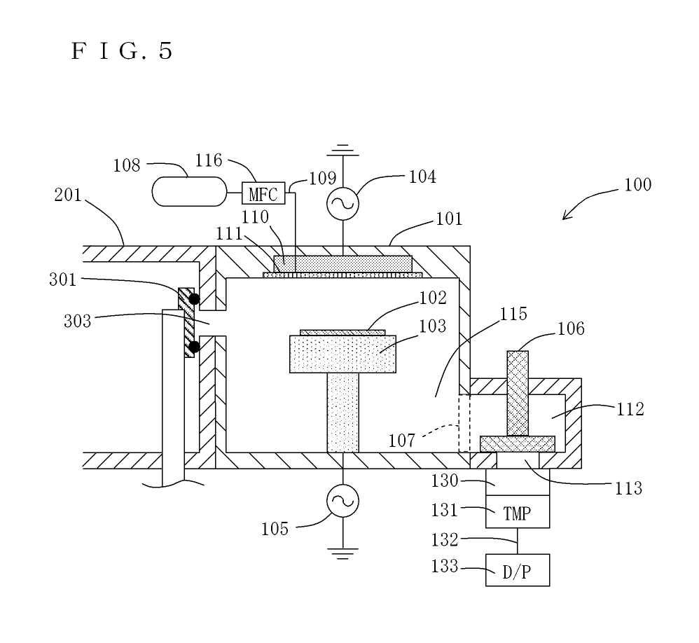

Before starting to describe the manufacturing method according to the present exemplary embodiment, a device used for contact dry etching and nitrogen plasma treatment in the manufacturing method according to the present exemplary embodiment is described referring to FIGS. 4 and 5. FIG. 4 is a schematic drawing of a plasma treatment device 100 according to the present exemplary embodiment 1, and FIG. 5 is a sectional view of the plasma treatment device 100 according to the present exemplary embodiment 1. A reference numeral 102 illustrated in FIG. 5 is a semiconductor wafer.

There are FOUP (Front Open Unified Pod) setting sections 501 on the front side of the device, and an atmosphere loader 502 is connected to the FOUP setting sections 501. The atmosphere loader 502 is provided with a transport mechanism (not illustrated in the drawing) and a notch alignment 503. The atmosphere loader 502 is further provided with load lock chambers 401. The atmosphere loader 502 and the load lock chambers 401 are connected so as to communicate with each other. The load lock chambers 401 and a wafer vacuum transport chamber 201 are connected so as to communicate with each other. The wafer vacuum transport chamber 201 and etching chambers 101 are connected so as to communicate with each other.

The atmosphere loader 502 and the wafer vacuum transport chamber 201 disposed facing each other are respectively connected to the load lock chambers 401. Openable/closable gate valves 301A, 301b, and 301C are respectively provided between the atmosphere loader 502 and the load lock chamber 401, between the wafer vacuum transport chamber 201 and the load lock chamber 401, and between the wafer vacuum transport chamber 201 and the etching chamber 101. Accordingly, the load lock chamber 401 can be isolated from the atmosphere loader 502 and the wave vacuum transport chamber 201.

The device is adapted to transport a semiconductor wafer into the load lock chamber 401 at the atmospheric pressure and then close the gate valve 301A so that the load lock chamber 401 at the atmospheric pressure is vaccumized by, for example, a dry pump . The transport mechanism (not illustrated in the drawing) is loaded in the wafer vacuum transport chamber 201. The etching chamber 101 can be isolated from the wafer vacuum transport chamber 201 by the gate valve 301 B so that ambient air in the etching chamber 101 is left intact during etching. Below is given a detailed description.

The semiconductor wafer (substrate) is removed from the FOUP setting section 501 by the transport mechanism of the atmosphere loader 502, and the removed semiconductor wafer is transported to the notch alignment 503 so that notches of the semiconductor wafer are aligned. After the notch alignment is done, the gate valve 301A between the atmosphere loader 502 and the load lock chamber 401 is opened to transport the semiconductor wafer to the load lock chamber 401. Then, the gate valve 301A is closed, and the load lock chamber 401 is vacuumized with the valve kept closed. After the load lock chamber 401 is finally in vacuum state, the gate valve 301 B on the side of the wafer vacuum transport chamber 201 is opened, and the semiconductor wafer is transported from the load lock chamber 401 into the wafer vacuum transport chamber 201 by the transport mechanism of the wafer vacuum transport chamber 201. Then, the gate valve 301C between the etching chamber 101 and the wafer vacuum transport chamber 201 is opened so that the semiconductor wafer is transported from the wafer vacuum transport chamber 201 into the etching chamber 101.

In the plasma treatment device 100, a process chamber 101 in charge of plasma treatment and the semiconductor wafer transport chamber 201 are continuous to each other through a semiconductor wafer transport path 303 (see FIG. 5), and a gate valve 301 for opening and closing the semiconductor wafer transport path 303 is provided. The gate valve 301 blocks plasma ambient in the process chamber 101. The etching chamber 101 is used as the process chamber 10.

As illustrated in FIG. 5, the semiconductor wafer transport chamber 201 has the transport mechanism (not illustrated in the drawing) which transports the semiconductor wafer 102 into and out of the process chamber 101. The gate valve 301 is provided on the side of the semiconductor wafer transport chamber 201. The process chamber 101 is provided with a semiconductor wafer stage 103 in which the semiconductor wafer 102 is placed. The semiconductor wafer stage 103 is provided with a lower power supply 105, and an upper electrode 105 is embedded in a top portion of the chamber. The upper electrode 110 is connected to an upper power supply 104. According to the structural characteristic, the process chamber 101 functions as a two-frequency device.

The plasma treatment device 100 has a gas supply system 109. The gas supply system 109 has a gas source 108, wherein gas supplied from the gas supply system 109 blasts into the upper electrode 110 through a plurality of holes formed in a gas blast plate 111 and further blasts into the process chamber 101. The plasma treatment device 100 has an exhaust system 115. The exhaust system 115 has an exhaust unit 107 in a lower section of a side wall thereof on the opposite side of the semiconductor wafer transport path 303. The exhaust unit 107 communicates with an exhaust region 112. In a bottom section of the exhaust region 112 are provided an exhaust port 113, an exhaust gate valve 106 which opens and closes the exhaust port 113, a turbo molecular pump 131 which communicates with the exhaust port 113, and an exhaust pipe 132. The gas in the process chamber 101 is discharged outside through the exhaust unit 107, exhaust region 112, and exhaust port 113.

Below is described the semiconductor device manufacturing method according to the present exemplary embodiment in which the device for contact dry etching and nitrogen plasma treatment described so far is used. First, gate electrodes 14 are formed on a semiconductor substrate (semiconductor wafer) 16, and a first side wall 11 is formed on a side wall of each of the gate electrodes 14. Then, a second side wall 12 is formed on an outer side of the first side wall 11, and a third side wall 13 is further formed on an outer side of the second side wall 12 (see FIG. 2A).

Then, a stressor SiN film 17 is formed so as to cover the gate electrodes (see [a] of FIG. 1A and FIG. 1B, and FIG. 2B). An inter-layer insulation film 18 is formed on the stressor SiN film, and an upper surface of the inter-layer insulation film 18 is flattened by, for example, CMP (see [b] of FIG. 1A and FIG. 1B, and FIG. 2C). Then, a resist pattern 19 is formed by lithography on the upper surface of the inter-layer insulation film 18 (see [c] of FIG. 1A and FIG. 1 B, and FIG. 2D).

The inter-layer insulation film 18 is partly removed by dry etching in which the resist pattern 19 is used as a mask so that contact holes 21 are formed (see [d] of FIG. 1A and FIG. 1B, and FIG. 2E). The inter-layer insulation film 18 is removed until the stressor SiN film 17 is exposed at bottoms of the contact holes. Then, the resist pattern 19 is removed by ashing (see [e] and [f] of FIG. 1A and FIG. 1B, and FIG. 2F). After the resist pattern 19 is removed, the stressor SiN film 17 exposed at the bottoms of the contact holes 21 is removed by dry etching (see [g], [i] and [j] of FIGS. 1A and 1B, and FIG. 2G). Finally, the semiconductor substrate 16 is ashed and then washed (see [i] and [j] of FIGS. 1A and 2B). Then, embedded wirings (not illustrated in the drawing) made of tungsten are formed in the contact holes 21.

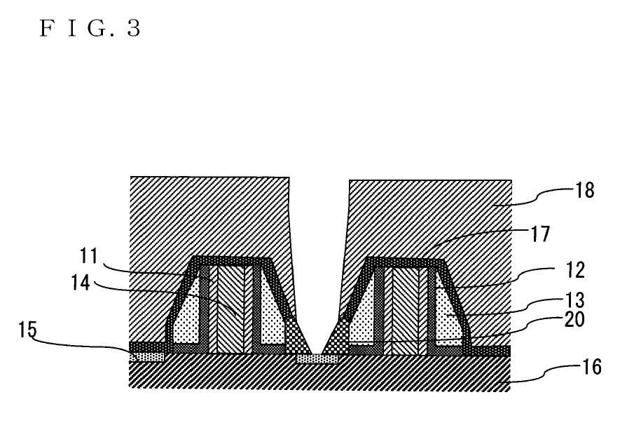

The semiconductor device manufacturing steps described so far are basically similar to the conventional manufacturing steps. As illustrated in FIG. 3, the polymer produced during dry etching (see [d] and [g] of FIGS. 1A and 1B) reacts with the atmospheric moisture content, generating hydrofluoric acid, and the hydrofluoric acid possibly dissolves the stressor SiN film 17. When the stressor SiN film 17 is dissolved, the embedded wirings show abnormal wiring resistance values (become variable).

To prevent the variability of the wiring resistances, the present exemplary embodiment performs steps [h-1], [h-2], and [h-3] steps illustrated in FIG. 1A between the step of removing the stressor SiN film 17 by etching ([g] of FIG. 1A) and the step of removing the resist pattern by ashing ([i] of FIG. 1A).

First, the step [h-1] is described. After the stressor SiN film (liner film) 17 is removed by dry etching ([g] step), the semiconductor substrate 16 is subjected to nitrogen plasma treatment to remove a C—F-based polymer therefrom. The nitrogen plasma treatment is performed immediately after the dry etching in the chamber where the dry etching of [g] is performed.

Conventionally, the C—F-based polymer is removed by using oxygen plasma. However, the removal using oxygen plasma is inapplicable to the structure of the semiconductor device according to the present invention because the bottom sections of the contact holes may be thereby oxidized. Another option for removing the C—F-based polymer is to use a gas including hydrogen. However, the option is not recommendable because hydrogen possibly reacts with fluorine in the polymer, generating hydrofluoric acid.

In the [h-1] step according to the present exemplary embodiment, the nitrogen plasma treatment is chosen in view of the disadvantages of the other techniques. The nitrogen plasma treatment is considered to remove the C—F-based polymer as expressed in the following reaction formula 1).

CxFy+xN→xCn+yF 1)

It was learnt from the tests conducted by the inventors of the present invention that the C—F-based polymer generated in the contact holes 21 can be reliably removed when a lower RF power (bypass power: voltage) supplied to the semiconductor wafer 102 through the lower electrode 105 is higher than an upper RF power (voltage) supplied to the upper electrode 110 so that top power/bypass power is at most 1. In the present exemplary embodiment, therefore, the lower RF power to be supplied to the semiconductor wafer 102 through the lower electrode 105 is higher than the upper RF power (upper RF power/lower RF power<1) to surely remove the fluorine component using Cu—N. Further, a volume of nitrogen is increased because it is necessary to supply enough volume of nitrogen to ensure the reaction, and time long enough is set for the nitrogen treatment.

While the fluorine component is being removed by the nitrogen plasma treatment, the fluorine component once removed may adsorb again to the semiconductor wafer. The present exemplary embodiment employs the following two actions to prevent the fluorine component from adsorbing again to the semiconductor wafer.

Action 1

The action 1 focuses on temperature. A length of time during which the molecule adsorbed to the solid surface stays thereon is expressed by the following formula 2).

T=T0×exp(ε0/kT) (2)

T represents a constant, T represents a solid surface temperature, ε represents an activation energy for desorption of a molecule (KJ/molecules), and k represents the Boltzmann's constant.

As is clear from the formula 2), the length of time during which the molecule stays on the solid surface is shorter as the solid surface temperature is higher, meaning that it becomes more difficult for the fluorine once desorbed from the semiconductor wafer 102 to adsorb thereto again as the solid surface temperature is higher. Thus, the semiconductor wafer 102 preferably has a higher surface temperature. In the [h-1] step according to the present exemplary embodiment, the semiconductor wafer 102 has a surface temperature equal to or higher than 30° C. Too a high temperature would cause problems, for example, difficulty in adsorption of the semiconductor wafer 102 to an electrostatic chuck (ESC). Therefore, an upper limit of the temperature is around 60° C.

Action 2

An effective way to prevent the fluorine desorbed from the semiconductor wafer 102 from adsorbing thereto again is to intensify an exhaust power, based on which the action 2 is taken. A length of time during which the gas is suspended in the chamber is expressed by the following formula 3).

T=P×V÷Q (3)

T represents the length of time during which the gas stays in the reaction chamber, P represents a gas pressure, V represents a reaction chamber capacity, and Q represents a gas flow rate.

As is clear from the formula 3), the stay time is shorter as the flow rate is larger. It was learnt from the conducted test that a favorable result can be obtained with the flow rate=500 sccm and the stay time T=at most 0.2 sec.

All of the requirements of the [h-1] described so far (nitrogen plasma treatment) are listed below.
upper RF power 350-600 W
lower RF power: 350-600 W (on the condition that upper RF power/lower RF power<1)
nitrogen gas flow rate: 500-1,000 sccm
temperature of semiconductor wafer stage: 30-60° C.

Next, the [h-2] and [h-3] steps are described below. In the [h-2] step, a carbon monoxide gas is introduced into the chamber after the [h-1] step (nitrogen plasma treatment) to completely remove the fluorine possibly left after the [h-1] step. The introduced carbon monoxide generates a reaction expressed by the following reaction formula 4).

CO+F→COF 4)

Accordingly, the fluorine is prevented from adsorbing to the semiconductor wafer 102 again and discharged from the chamber in the form of a COF gas. After the [h-2] step (CO purge), the nitrogen purge step ([h-3 step) is repeated so that the ashing treatment ([i] step) can be performed.

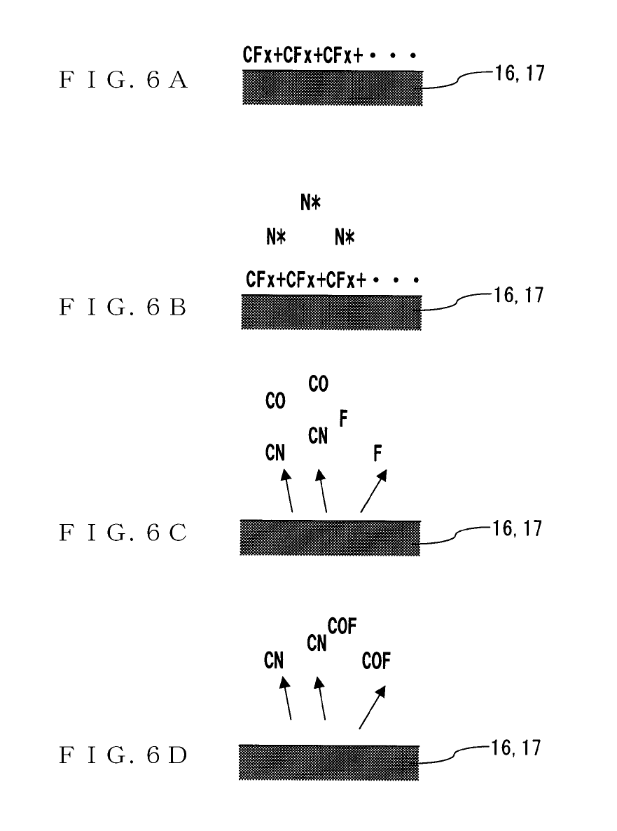

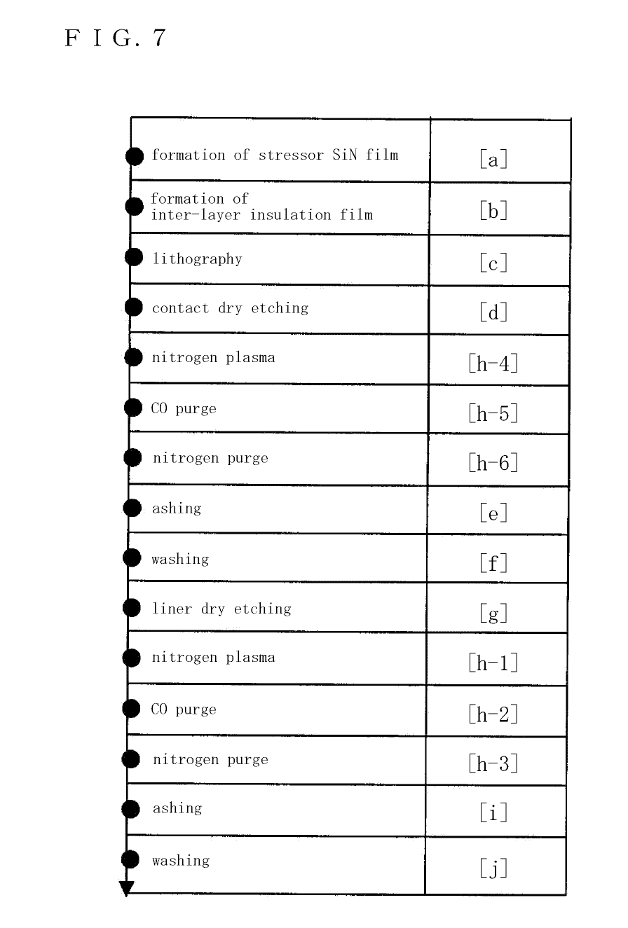

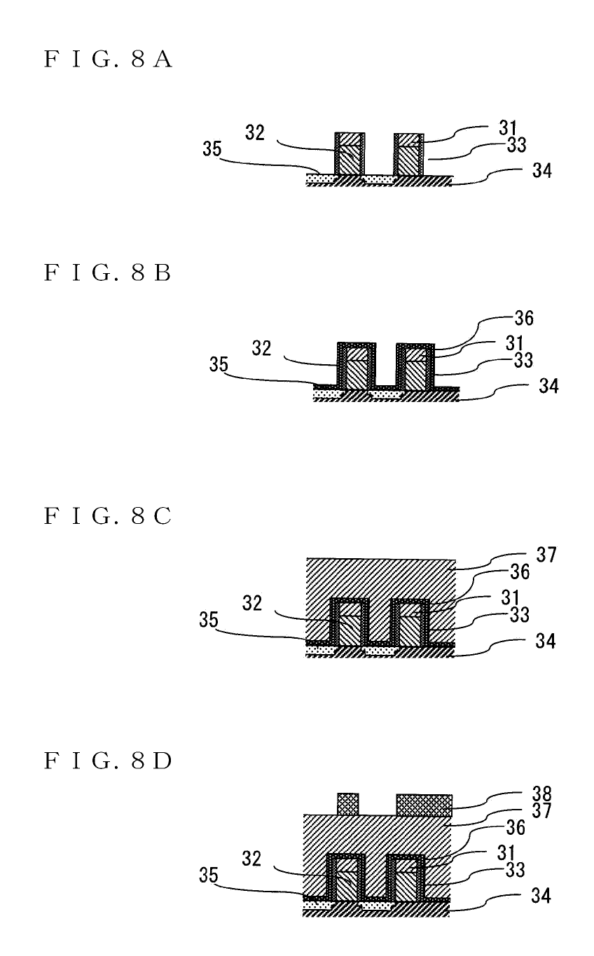

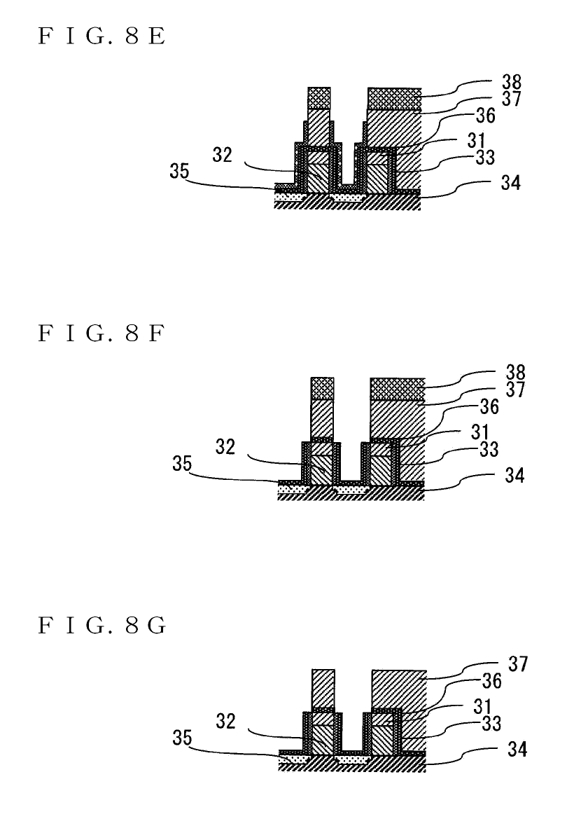

FIGS. 6A-6D illustrate the mechanism of the fluorine removal described so far. A CFx polymer is generated on the semiconductor substrate 16 or the stressor SiN film 17 after dry etching (see FIG. 6A). The nitrogen plasma treatment is thereafter performed so that the CFx polymer is decomposed into CN and F (see FIGS. 6B and 6C). Then, carbon monoxide gas is flown onto the semiconductor substrate 16 or the stressor SiN film 17 so that the CN and COF are discharged in the form of gas (see FIG. 6D).

There might be the fluorine component still left on the semiconductor wafer. Therefore, the post-treatment semiconductor wafer 102 is not exposed to atmosphere but is retained under a nitrogen atmosphere. To more safely retain the semiconductor wafer 102, a nitrogen gas is used to revert the load lock chamber 401 from vacuum to the atmospheric pressure. The atmosphere loader 502 and the FOUP setting sections are also filled with the nitrogen gas. This arrangement can prevent the residual fluorine from reacting with the atmospheric moisture content, generating hydrofluoric acid, just in case where there is the fluorine still remaining on the semiconductor wafer 102.

The two-frequency etching chamber (process chamber) 101 is used in the present exemplary embodiment. The etching technique can be used without any dependence on a plasma source which emits, for example microwave. To more effectively remove the fluorine, it is desirable to use a device capable of controlling the RF power on the bias side of the semiconductor wafer (lower RF power).

### Exemplary Embodiment 2

A semiconductor device manufacturing method according to an exemplary embodiment 2 of the present invention is described below referring to a manufacturing flow illustrated in FIG. 7. According to the exemplary embodiment 1, the [h-1] step (nitrogen plasma treatment), the [h-2] step (CO purge), and the [h-3] step (nitrogen purge) are performed after the [g] step (dry-etching removal of the stressor SiN film 17). The present exemplary embodiment is technically characterized in that a [h-4] step (second nitrogen plasma treatment), a [h-5] step (second CO purge), and a [h-6] step (second nitrogen purge) are performed after the [d] step (contact dry etching).

Though largely depending on conditions, the [d] step (contact dry etching) is unlikely to produce a fluorocarbon-based gas as a polymer at the bottoms of the contact holes 21. However, the fluorocarbon-based gas may be generated as a polymer at the bottoms of the contact holes 21 under a certain condition. Therefore, it is still possible that fluorine is produced from the fluorocarbon-based gas thus generated when the semiconductor wafer 102 is exposed to atmosphere, dissolving the stressor SiN film 17. To avoid the dissolution of the stressor SiN film 17, the present exemplary embodiment performs the [h-4] step (second nitrogen plasma treatment), [h-5] step (second CO purge), and [h-6] step (second nitrogen purge) after the [d] step (contact dry etching).

### Exemplary Embodiment 3

In the exemplary embodiment 1, the volume of fluorocarbon-based gas used to remove the stressor SiN film 17 by dry etching may be largely reduced because the stressor SiN film 17 is very thin. In such a case, the [h-1] step (nitrogen plasma treatment) is omitted, and the [h-2] step (introduce carbon monoxide into the chamber) is performed, so that the fluorine is prevented from adsorbing to the semiconductor wafer 102 again to be discharged from the chamber as COF gas.

As far as a very small volume of fluorocarbon-based gas is used, all of the [h-1] step (nitrogen plasma treatment), the [h-2] step (CO purge), and the [h-3] step (nitrogen purge) may be omitted, and the semiconductor wafer 102 may be retained under the nitrogen atmosphere without being exposed to atmosphere. To more safely retain the semiconductor wafer 102, the nitrogen gas is used to revert the load lock chamber 401 from vacuum to the atmospheric pressure. The atmosphere loader 502 and the FOUP setting sections are also filled with the nitrogen gas. This arrangement can prevent the residual fluorine from reacting with the atmospheric moisture content, generating hydrofluoric acid, just in case where there is the fluorine still remaining on the semiconductor wafer 102.

### INDUSTRIAL APPLICABILITY

As described thus far, the present invention is technically advantageous in that dissolution of the stressor SiN film, which is a cause of wiring resistance variability in semiconductor device manufacturing methods conventional employed, is prevented for better stability. The manufacturing method according to the present invention is also advantageous in view of productivity.

### DESCRIPTION OF REFERENCE SYMBOLS

11 first side wall
12 second side wall
13 third side wall
14 gate electrode
15 diffusion region
16 semiconductor substrate
17 stressor SiN film
18 inter-layer insulation film
19 resist pattern
20 corrosion of stressor SiN film
101 process chamber
102 semiconductor wafer
103 semiconductor wafer stage
104 upper electrode
105 lower electrode
106 exhaust gate valve
107 exhaust unit
108 gas supply source
109 gas supply port
110 upper electrode
111 gas blast plate
112 exhaust region
113 exhaust port
114 gas flow rate controller
116 process gas flow rate controller
120 control and computation device
130 APC valve
131 turbo molecular pump
132 exhaust pipe
133 dry pump
201 wafer vacuum transport chamber
301A-301C gate valve
303 semiconductor wafer transport path
401 load lock chamber
501 FORP setting section
502 atmosphere loader
503 notch alignment

What is claimed is:

1. A method for manufacturing a semiconductor device, including:
a first step for forming a stressor SiN film on a gate electrode formed on a semiconductor substrate;
a second step for forming an inter-layer insulation film on the stressor SiN film;
a third step for providing a resist pattern on the inter-layer insulation film and then dry-etching the inter-layer insulation film;
a fourth step for removing the resist pattern and then dry-etching the stressor SiN film; and
a fifth step for subjecting the semiconductor substrate to nitrogen plasma treatment after the third step or the fourth step.

2. The method for manufacturing a semiconductor device as claimed in claim 1, wherein
the inter-layer insulation film is dry-etched until the stressor SiN film is exposed in the third step, and
the stressor SiN film exposed at a bottom section of the inter-layer insulation film is dry-etched in the fourth step.

3. The method for manufacturing a semiconductor device as claimed in claim 1, wherein
the fifth step is performed at a time point after the third step and at a time point after the fourth step.

4. The method for manufacturing a semiconductor device as claimed in claim 1, wherein
the fifth step is performed after the semiconductor substrate is placed in a chamber and nitrogen is introduced into the chamber, and
a flow rate of the nitrogen introduced into the chamber is set to at least 500 sccm.

5. The method for manufacturing a semiconductor device as claimed in claim 1, wherein
the fifth step is performed after the semiconductor substrate is placed in a chamber and nitrogen is introduced into the chamber, and
a flow rate of the nitrogen introduced into the chamber is set so that a length of time during which the nitrogen stays in the chamber is at most 0.2 sec.

6. The method for manufacturing a semiconductor device as claimed in claim 1, wherein
a surface temperature of the semiconductor substrate in the fifth step is set to 30-60° C.

7. The method for manufacturing a semiconductor device as claimed in claim 4, wherein
the fifth step is performed after the semiconductor substrate is placed in a chamber and an upper RF power and a lower RF power are applied to the chamber, and a ratio of the upper RF power to the lower RF power (upper RF power/lower RF power) is set to at most 1.

8. The method for manufacturing a semiconductor device as claimed in claim 5, wherein
the fifth step is performed after the semiconductor substrate is placed in a chamber and an upper RF power and a lower RF power are applied to the chamber, and a ratio of the upper RF power to the lower RF power (upper RF power/lower RF power) is set to at most 1.

9. The method for manufacturing a semiconductor device as claimed in claim 1, wherein
at least the fifth step in the first-fifth steps is performed after the semiconductor substrate is placed in a chamber,
the method further including a six step for introducing carbon monoxide into the chamber after the fifth step is over

10. The method for manufacturing a semiconductor device as claimed in claim 1, further including a seventh step for retaining the semiconductor substrate after the fifth step is over under a nitrogen atmosphere.

11. A method for manufacturing a semiconductor device, including:
a first step for forming a stressor SiN film on a gate electrode formed on a semiconductor substrate;
a second step for forming an inter-layer insulation film on the stressor SiN film;
a third step for providing a resist pattern on the inter-layer insulation film and then dry-etching the inter-layer insulation film; and
a fourth step for removing the resist pattern and then dry-etching the stressor SiN film, wherein
at least the third step and the fourth step in the first-fourth steps are performed after the semiconductor substrate is placed in a chamber, and
the method further including a fifth step for introducing CO into the chamber after the third step or the fourth step is over.

12. A method for manufacturing a semiconductor device, including:
a first step for forming a stressor SiN film on a gate electrode formed on a semiconductor substrate;
a second step for forming an inter-layer insulation film on the stressor SiN film;
a third step for providing a resist pattern on the inter-layer insulation film and then dry-etching the inter-layer insulation film;
a fourth step for removing the resist pattern and then dry-etching the stressor SiN film; and
a fifth step for retaining the semiconductor substrate under a nitrogen atmosphere after the third step or the fourth step is over.
